(19) United States
(12) Patent Application Publication
(10) Pub. No.: US 2019/0331773 A1
(43) Pub. Date: Oct. 31, 2019

(54) QUADRUPLE WELL FOR ELECTRICAL CROSS-TALK NOISE ATTENUATION

(71) Applicant: AVAGO TECHNOLOGIES GENERAL IP (SINGAPORE) PTE. LTD., Singapore (SG)

(72) Inventors: Reinhard Enne, Hofstetten-Grünau (AT); Milos Davidovic, Vienna (AT); Gunther Leopold Steinle, Regensburg (DE)

(21) Appl. No.: 15/964,669

(22) Filed: Apr. 27, 2018

(51) Int. Cl. G01S 7/486; H01L 31/02; H01L 31/0224; H01L 31/0352; G01S 17/08

(52) U.S. Cl. CPC G01S 7/4861; H01L 31/02019; G01S 17/08; H01L 31/035272; H01L 31/022416

(57) ABSTRACT

Systems and circuits directed to a time-of-flight measurement system are provided. More specifically, the time-of-flight measurement system may include an optical sensor module including a substrate of a first conductivity type having an epitaxial layer disposed thereon, a photodetector formed in the first epitaxial layer, a deep well of a second conductivity type formed in the first epitaxial layer, a deep well of the first conductivity type formed in the deep well of the second conductivity type, a well of the second conductivity type formed in the deep well of the first conductivity type, and a well of the first conductivity type formed in the deep well of the first conductivity type. The time-of-flight measurement system may include control logic configured to determine a distance based on a time-of-flight value received from the photodetector.

### FIELD OF THE DISCLOSURE

The present disclosure is generally directed toward monolithically integrated photodetectors and an influence of substrate noise on a detected signal.

### BACKGROUND

Time-of-flight measurement instruments generally include a range imaging camera system that resolves distance based on the known speed of light by measuring the time-of-flight of a light signal between the camera and the subject for each point of the image. In some instances, the time-of-flight measurement instrument may utilize one or more photon emitters, such as a laser or other light source, to emit photons, or light, directed to the subject. The time-of-flight measurement instrument may utilize an optoelectric sensor including a photodetector, such as a multi-pixel distance and motion measurement sensor, to receive photons reflected by the subject. The time-of-flight measurement instrument and/or the multi-pixel distance and motion measurement sensor may then determine the range, or distance, between the camera and the object.

The photodetector and the circuitry for the photon emitter may be formed in a single package, and in some instances, on a single die or substrate. However, when the photodetector and the circuitry for photon emitter are formed on a single die and/or substrate, the effect of noise at the photodetector strongly limits the overall system performances. That is, the photodetector generates current at picoamp levels while the operation of the circuitry may require the generation of milliamps. For example, the circuitry may run synchronously at a clock frequency that the photodetector utilizes for detection. As a more specific but non-limiting example, the circuitry may generate more than 100 milliamps current to drive an emitter. When utilizing a single die, or substrate, and sharing an anode, or cathode, electrical crosstalk between the emitter and the photodetector creates noise and alters the picoamp current resulting from photon detection.

### BRIEF DESCRIPTION OF THE DRAWINGS

The present disclosure is described in conjunction with the appended figures, which are not necessarily drawn to scale:

FIG. 1 is a block diagram depicting a time-of-flight measurement system in accordance with at least some embodiments of the present disclosure;

FIG. 2 depicts a block diagram illustrating a top view of a photodetector and emitter circuitry in accordance with at least some embodiments of the present disclosure; and

FIG. 3 depicts a block diagram illustrating a side view of the photodetector and emitter circuitry in accordance with at least some embodiments of the present disclosure.

### DETAILED DESCRIPTION

Various aspects of the present disclosure will be described herein with reference to drawings that are schematic illustrations of idealized configurations. As such, variations from the shapes of the illustrations as a result, for example, manufacturing techniques and/or tolerances, are to be expected. Thus, the various aspects of the present disclosure presented throughout this document should not be construed as limited to the particular shapes of elements (e.g., regions, components, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another—although some features or elements may exhibit discrete changes as well. Thus, the elements illustrated in the drawings are schematic in nature and their shapes are not intended to be limited to the precise shape of an element and are not intended to limit the scope of the present disclosure.

It will be understood that when an element such as a region, component, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” or “established” on another element, it can be grown, deposited, etched, attached, connected, coupled, or otherwise prepared or fabricated on the other element or an intervening element.

Furthermore, relative terms, such as “lower” or “bottom” and “upper” or “top” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower” can, therefore, encompass both an orientation of “lower” and “upper” depending of the particular orientation of the apparatus. Similarly, if an apparatus in the drawing is turned over, elements described as “below” or “beneath” other elements would then be oriented “above” the other elements. The terms “below” or “beneath” can therefore encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

It is with respect to the above-noted challenges that embodiments of the present disclosure were contemplated. In particular a time-of-flight system and a photodetector monolithically formed with circuitry are provided to address the need to reduce crosstalk between the photodetector and circuitry.

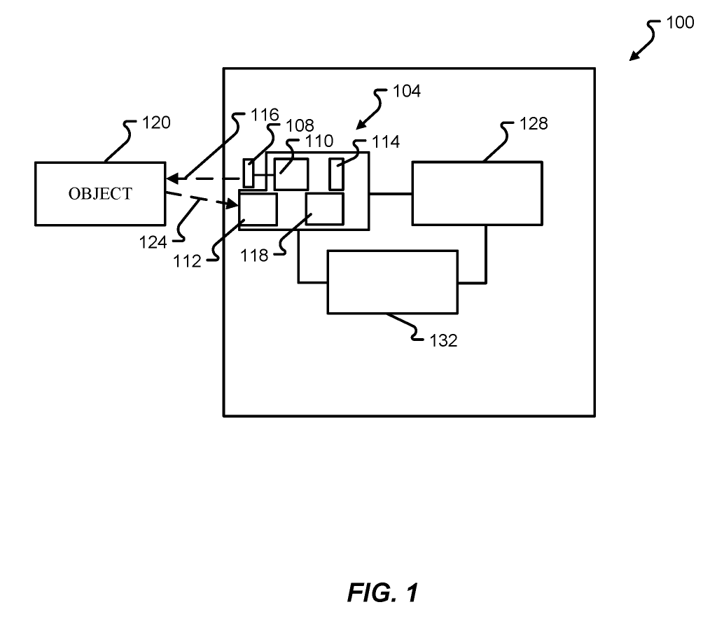

In accordance with at least one embodiment of the present disclosure, FIG. 1 depicts a time-of-flight measurement system 100. The time-of-flight measurement system 100 may include an optical sensor module 104 having photon circuitry 110 for driving a photon emitter 108 and an optoelectric sensor 112. The photon emitter 108 is shown as being provided on a separate substrate as the optoelectric sensor 112, although it should be appreciated that embodiments of the present disclosure are not so limited. The photon emitter 108 may be driven by the photon circuitry 110 and may emit light having one or more wavelengths; such light may travel through space between the photon emitter 108 and an object 120 as a light signal 116. The light signal 116 may encounter the object 120 and be reflected back to the optoelectric sensor 112 of the time-of-flight measurement system 100 as a reflected light signal 124. The time-of-flight measurement system 100, and more specifically, the photodetector and emitter 104, may determine an amount of time between when the photon emitter 108 emitted the light and when the optoelectric sensor 112 received the reflected light, known as time-of-flight. As the light signal 116 and reflected light signal 124 travel through space at, or close to, the speed of light, the time-of-flight may be utilized to determine a distance between the optical sensor module 104 of the time-of-flight measurement system 100 and the object 120.

In accordance with at least one embodiment of the present disclosure, the optical sensor module 104 may be monolithically integrated into a single die. Stated another way, the photon emitter circuitry 110 and the optoelectric sensor 112 may reside at a shared substrate. Alternatively, or in addition, any circuitry that runs synchronously at a clock frequency in which the photodetector operates may reside at the shared substrate. The shared substrate may be part of a standalone package or device. Alternatively, or in addition, the shared substrate may be part of an ASIC. For example, the optical sensor module 104 may be an ASIC and may further include time-of-flight circuits 118, one or more clocks 114, and one or more power regulation means. The time-of-flight measurement system 100 may include a CPU/processor 128 to receive a time-of-flight quantity and determine an overall distance between the optical sensor module 104 and the object 120. The CPU/processor 128 may then store the determined distance in the memory 132. Alternatively, or in addition, the time-of-flight quantity and/or the determined distance may be determined at the optical sensor module 104 and stored in the memory 132, where the CPU/processor 128 may access the memory 132. The CPU/processor 128 may be referred to herein as control logic and may be executed in separate processing IC chips or on control logic that is integrated with one of the other substrates depicted and described herein.

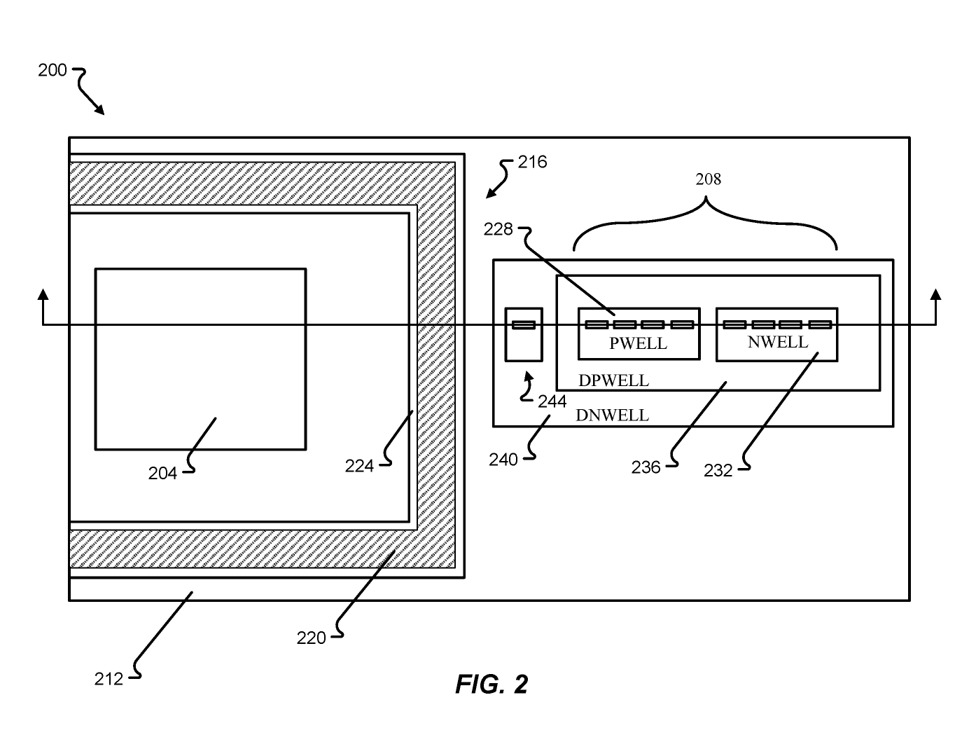

As previously discussed, the photon emitter circuitry 110 and the optoelectric sensor 112 may reside at the same substrate, as illustrated in FIG. 2. The optoelectric sensor 112 may include, or otherwise be known as, a photodetector 204. The photodetector 204 may include a plurality of photodiodes forming pixels configured to receive light and convert the light into a corresponding amount of current. The photodetector 204 may be characterized through several parameters among which include, but are not limited to, its capacitance, quantum efficiency, and noise performance. The capacitance, also known as C_{DET}, is the capacitance of the photodetector with respect to the substrate in which the photodetector is formed. For example, C_{DET} may be 200 fF. Quantum efficiency is the ability of a photodetector to convert incident light, such as a photon, into an electron-hole pair, while the noise performance may be a measurement with respect to how system noise affects the photodetector's ability to accurately convert detected light into a current.

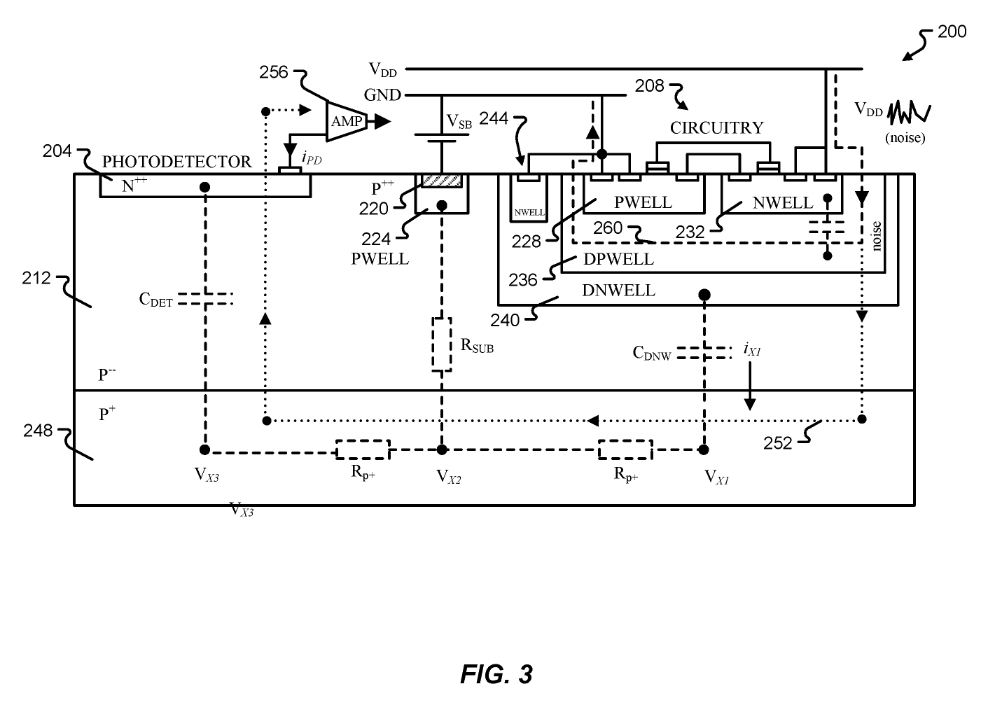

As illustrated in FIG. 2, the photodetector 204 may reside on a same substrate 212 as the circuitry 208, where the circuitry 208 may be circuitry configured to drive a photon emitter to emit light and/or other circuitry utilized in the time-of-flight conversion process. The photodetector 204 may be separated from the circuitry 208 with the P-well contact ring 216, where the P-well contact ring 216 includes a P⁺⁺ impurity region 220 formed in a P-well 224 and the P-well contact ring 216 surrounds the photodetector 204. The P-well contact ring 216 may ensure a solid connection underneath the opto-sensitive area of the photodetector 204 to enhance the light-to-current conversion performance of the photodetector 204. The circuitry 208 may include a quadruple well including a P-well 228, N-well 232, deep P-well DPwell 236, and deep N-well DNwell 240. That is, the circuitry 208 may be insulated with a deep NWELL 240 which serves to decouple the PMOS transistors (realized in NWELL 232) or NMOS transistors (realized in PWELL 228) from the substrate. The deep p-doped well DPWell 236 is connected via PWELL 228 which serves as the electrode at the same time. The circuitry 208 may further include an electrode 244 coupled to the DNwell 240 and the N-well 232 such that the DNwell 240 and the N-well 232 are at a same potential, for reasons that will be discussed with respect to FIG. 3.

FIG. 3 depicts a side view of the photodetector and emitter circuitry of FIG. 2 along the section line A-A, in accordance with at least one embodiment of the present disclosure. In cases of fast optical receivers, a low-doped P⁻⁻ epitaxial layer 212 is utilized to ensure that the conversion from light to electricity occurs in a timely manner with respect to the speed at which the photodetector 204 operates. The epitaxial layer 212 minimizes a diffusion portion of the generated i_{PD} optocurrent that may be generated. The diffusion effect of the current i_{PD} is generally responsible for delaying the conversion of electron-hole pairs into photocurrent and therefore slows the response time of the photodetector 204. Accordingly, if the P⁻⁻ epitaxial layer 212 layer is not included, the speed of the photodetector 204 will be limited. Thus, a structure without the P⁻⁻ epitaxial layer 212 layer is possible if a high-speed photodetector is not needed.

As previously described, the circuitry 208 may be insulated with a deep NWELL 240 which serves to decouple the NMOS transistors from the P+ substrate 248. With respect to the P⁺ substrate, the DNwell 240 may be considered to be a large reversely biased diode having a capacitance equal to C_{DNW}. Thus, in order to avoid any direct diode biasing, the DNwell 240 has to be biased at the highest voltage that is present within the contents of the well, which is normally V_{DD}. Since the same V_{DD} voltage is used to supply all of the digital and analog circuitry within the optical sensor module 200, V_{DD} is normally very noisy. Thus, when the parasitic capacitance C_{DNW} is considered, any voltage fluctuation of V_{DD} will cause a proportional voltage change underneath DNwell 240, referred herein as V_{X1}. The noise current injected into the substrate 248 underneath the DNwell 240 may be expressed as depicted in Equation 1.

$${i}_{X 1} \approx {C}_{DNW} \frac{dVDD}{dt} \qquad Equation 1$$

That is, the current injected into the substrate underneath the DNwell 240 due to noise will form a loop to ground via all the other structures realized on the chip, represented by the dotted line current path 252. Where the substrate shows certain resistances, the current injected into the substrate underneath the DNwell 240 due to noise causes voltage drops across Rₚ_{⁺} and R_{SUB}. As result the initial voltage fluctuations of V_{DD} propagate into the substrate 248 (the current injected into the substrate underneath the DNwell 240 due to noise V_{X2}, V_{X3}˜V_{X1}) and disturb other structures such as the photodetector 204. Thus, it is important to keep the voltage underneath the photodetector very stable. For example, if the photodetector 204 has a capacitance of C_{DET} equal to 200 fF, and the photodetector 204 is to detect sub-nanowatt optical signals having a bandwidth of a few hundreds of MHz, the millivolt change of V_{X3} within 1 ns can be calculated; such a change would disturb the detected electrical representation of the optical signal at the photodetector 204. Moreover, the photodetector 204 may detect 500 pico amps; however, the circuitry 208 may be generating milliamps (causing a six times difference in magnitude). Because the photodetector 204 and the circuitry 208 are on the same die, electric cross talk is created which introduces noise to the photodetector 204. More specifically, the milliamp current generated by circuitry 208 will cause a voltage drop at V_{DD}, which may be in the 100 mV range; subsequently current i_{X1} will be injected into the shared substrate. This injected current will in turn generate V_{X3} voltage fluctuation which then generates a “false” photocurrent.

A P-well contact ring 216 may surround each and every circuit block to pick up any noise in the substrate caused by the circuitry and consequently may provide a better V_{X3} voltage stability. However, considering the P⁻⁻ epitaxial layer 212 included for better dynamic photon detection, such P⁻⁻ layer 212 will increase the series resistance R_{SUB} between the contact and the underlying P⁺ layer 248. As a consequence, the noise pick-up effectiveness will depend on the ratio between the resistance of the P+ portion and resistance of the substrate R_{SUB}. Unfortunately, as the resistance of the P⁺ portion is much smaller than the resistance of the substrate RSUB, noise suppression of provided by the P-well contact ring 216 tends to be limited. Therefore, the noise which is present at DNwell 240 bias voltage (V_{DD} in this case and which is coming into the emitter of the transistor) will be coupled to the photodetector 204 via the P⁺ substrate 248 and will be noticeable at the photodetector amplifier 256. In other words, where the low doped P⁻⁻ layer 212 exists, once the noise is present at DNwell 240, the whole die and/or substrate is exposed to such noise.

In accordance with embodiments of the present disclosure, a deep P-well DPwell 236 may be used to insulate the N-well 232 from the deep N-well DNwell 240 which is generally reserved for PMOS transistors. Accordingly, an electrode 244 may connect the DNwell 240 to a common voltage that does not fluctuate, such as ground or any other stable voltage. Thus, if the DNwell 240 is connected or otherwise coupled to a ground, the DPwell 236 may need to be biased. Accordingly, the DPwell 236 can be connected or otherwise coupled to any voltage that is less than or equal to the voltage of the DNwell 240. In some instances, the DPwell 236 may be connected to ground as well, since n-channel MOSFETs may be located within this well. As previously discussed, another potential can be applied to the DPwell 236, however, such potential has to be lower than ground in order to keep the diode formed by the DNwell 240 and DPwell 236 reversely biased.

In accordance with at least one embodiment of the present disclosure, a low-doped epitaxial layer 212 having a P-conductivity type of a low doped P⁻⁻ impurity may be utilized. Such low-doped epitaxial layer 212 having the P-conductivity type of low doped P⁻⁻ impurity region 212 may be necessary for the photodetector 204 to operate effectively. Moreover, the DNwell 240 is to be biased to ground, which goes against general design guidance because the DNwell 240 is generally coupled to the highest possible voltage in order to inversely bias a p-n junction created by the DNwell 240 and the DPwell 236. Thus, the DPwell 236 and the P-well 228 are connected to a ground which shorts the DNwell 240 and the P-well 228 to create a highly sensitive substrate and eliminate the noise coming in on V_{DD} via the current path 260 such that the ground absorbs such noise. In accordance with at least one embodiment of the present disclosure, the DNwell 240 may be roughly three micrometers in depth while the P⁻⁻ epitaxial layer 212 may be 20 micrometers in thickness. Alternatively, or in addition, the P⁻⁻ epitaxial layer 212 may be less than 20 micrometers in thickness or greater than 20 micrometers in thickness. Alternatively, or in addition, a depth of the DNwell 240 may be less than or equal to three micrometers or greater than or equal to three micrometers.

In accordance with embodiments of the present disclosure, a semiconductor device is provided. The semiconductor device may include a substrate of a first conductivity type having an epitaxial layer disposed thereon and a photodetector formed in the first epitaxial layer. The semiconductor device may include a deep well of a second conductivity type formed in the first epitaxial layer and a deep well of the first conductivity type formed in the deep well of the second conductivity type. The semiconductor device may further include a well of the second conductivity type formed in the deep well of the first conductivity type, and a well of the first conductivity type formed in the deep well of the first conductivity type.

In accordance with embodiments of the present disclosure, a time-of-flight measurement system is provided. The time-of-flight measurement system may include an optical sensor module including a substrate of a first conductivity type having an epitaxial layer disposed thereon, a photodetector formed in the first epitaxial layer, a deep well of a second conductivity type formed in the first epitaxial layer, a deep well of the first conductivity type formed in the deep well of the second conductivity type, a well of the second conductivity type formed in the deep well of the first conductivity type, and a well of the first conductivity type formed in the deep well of the first conductivity type. The time-of-flight measurement system may further include at least one control logic to determine a distance based on a time-of-flight value received from the photodetector.

At least one aspect of the above embodiments may include where the deep well of the second conductivity type is connected to a ground potential. Another aspect of the above embodiments may include where the deep well of the first conductivity type is connected to the ground potential. A further aspect of the above embodiments may further include a first conductivity type contact ring formed around the photodetector. At least one aspect of the above embodiments may further include one or more transistors at least partially formed in the well of the second conductivity type and one or more transistors at least partially formed in the well of the first conductivity type. Another aspect of the above embodiments may include where a thickness of the deep well of the second conductivity type is greater than or equal to three micrometers. A further aspect of the above embodiments may include where an impurity concentration of the epitaxial layer is less than an impurity concentration of the substrate. Another aspect of the above embodiments may include where a thickness of the deep well of the second conductivity type is less than or equal to three micrometers. At least one aspect of the above embodiments may include where the second conductivity type is an N-type conductivity type.

In accordance with at least one embodiment of the present disclosure, an optical sensor module is provided. The optical sensor module may include circuitry. The circuitry may be coupled to an emitter. The optical sensor module may include first and second semiconductor wells formed at least partially within a first deep semiconductor well within the semiconductor substrate. The emitter circuitry may be configured to cause a photon emitter to emit light. The optical sensor module may further include a detector formed at least partially on the semiconductor substrate. The detector may be configured to detect light from the emitter. The optical sensor module may further include a second deep semiconductor well formed between the first deep semiconductor well and the semiconductor substrate, the second deep semiconductor well configuring the first deep semiconductor well to short noise-induced current to ground.

At least one aspect of the above embodiment may include where the first deep semiconductor well is connected to ground. Another aspect of the above embodiment may include where the second deep semiconductor well is connected to ground. At least one aspect of the above embodiment may further include a contact ring formed around the photodetector.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

1. A semiconductor device comprising:
a substrate of a first conductivity type having an epitaxial layer disposed thereon;
a photodetector formed in the first epitaxial layer;
a deep well of a second conductivity type formed in the first epitaxial layer;
a deep well of the first conductivity type formed in the deep well of the second conductivity type;
a well of the second conductivity type formed in the deep well of the first conductivity type; and
a well of the first conductivity type formed in the deep well of the first conductivity type.

2. The semiconductor device according to claim 1, wherein the deep well of the second conductivity type is connected to a ground potential.

3. The semiconductor device according to claim 2, wherein the deep well of the first conductivity type is connected to the ground potential.

4. The semiconductor device according to claim 1, further comprising:
a first conductivity type contact ring formed around the photodetector.

5. The semiconductor device according to claim 1, further comprising one or more transistors at least partially formed in the well of the second conductivity type and one or more transistors at least partially formed in the well of the first conductivity type.

6. The semiconductor device according to claim 1, wherein a thickness of the deep well of the second conductivity type is greater than or equal to three micrometers.

7. The semiconductor device according to claim 1, wherein an impurity concentration of the epitaxial layer is less than an impurity concentration of the substrate.

8. The semiconductor device according to claim 1, wherein the second conductivity type is an N-type conductivity type.

9. (canceled)

10. (canceled)

11. (canceled)

12. (canceled)

13. A time-of-flight measurement system comprising:
an optical sensor module including:
a substrate of a first conductivity type having an epitaxial layer disposed thereon,
a photodetector formed in the first epitaxial layer,
a deep well of a second conductivity type formed in the first epitaxial layer,
a deep well of the first conductivity type formed in the deep well of the second conductivity type,
a well of the second conductivity type formed in the deep well of the first conductivity type, and
a well of the first conductivity type formed in the deep well of the first conductivity type; and
control logic configured to determine a distance based on a time-of-flight value received from the photodetector.

14. The time-of-flight measurement system according to claim 13, wherein the deep well of the second conductivity type is connected to a ground potential.

15. The time-of-flight measurement system according to claim 14, wherein the deep well of the first conductivity type is connected to the ground potential.

16. The time-of-flight measurement system according to claim 13, further comprising:
a first conductivity type contact ring formed around the photodetector.

17. The time-of-flight measurement system according to claim 13, further comprising one or more transistors at least partially formed in the well of the second conductivity type and one or more transistors at least partially formed in the well of the first conductivity type.

18. The time-of-flight measurement system according to claim 13, wherein a thickness of the deep well of the second conductivity type is greater than or equal to three micrometers.

19. The time-of-flight measurement system according to claim 13, wherein an impurity concentration of the epitaxial layer is less than an impurity concentration of the substrate.

20. The time-of-flight measurement system according to claim 13, wherein the second conductivity type is an N-type conductivity type.

21. A semiconductor device, comprising:
a substrate of a first conductivity type having an epitaxial layer disposed thereon;
a photodetector formed in the first epitaxial layer;
a deep well of a second conductivity type formed in the first epitaxial layer;
a deep well of the first conductivity type formed in the deep well of the second conductivity type;
a well of the second conductivity type formed in the deep well of the first conductivity type;
a well of the first conductivity type formed in the deep well of the first conductivity type; and
a first conductivity type contact ring formed around the photodetector.

22. The semiconductor device of claim 21, further comprising:
one or more transistors at least partially formed in the well of the second conductivity type and one or more transistors at least partially formed in the well of the first conductivity type.

23. The semiconductor device of claim 21, wherein an impurity concentration of the epitaxial layer is less than an impurity concentration of the substrate.

24. The semiconductor device of claim 21, wherein the second conductivity type is an N-type conductivity type.
